(19) United States
(12) Patent Application Publication
(10) Pub. No.: US 2013/0280485 A1
(43) Pub. Date: Oct. 24, 2013

(54) Superhydrophobic and Oleophobic Functional Coatings Comprised of Grafted Crystalline Polymers Comprising Perfluoroalkyl Moieties

(71) Applicant: MASSACHUSETTS INSTITUTE OF TECHNOLOGY, Cambridge, MA (US)

(72) Inventors: Anna Maria Coclite, Cambridge, MA (US); Karen K. Gleason, Cambridge, MA (US); Yujun Shi, Calgary (CA)

(73) Assignee: Massachusetts Institute of Technology, Cambridge, MA (US)

(21) Appl. No.: 13/784,983

(22) Filed: Mar. 5, 2013

Related U.S. Application Data
(60) Provisional application No. 61/635,442, filed on Apr. 19, 2012.

(51) Int. Cl. C09D 133/16; C23C 16/02

(52) U.S. Cl. CPC C09D 133/16; C23C 16/0272
USPC 428/141; 428/336; 428/422; 442/118; 428/408; 428/304.4; 427/535; 524/544

(57) ABSTRACT

Described herein are methods of preparing superhydrophobic and oleophobic surfaces by grafting poly(perfluoroalkyl acrylate) chains on silicon substrates with initiated chemical vapor deposition. The grafting enhances the formation of the crystalline phase. The crystalline structures reduce the polymer chain mobility, resulting in nonwetting surfaces with respect to both water and mineral oil.

### RELATED APPLICATIONS

This application claims the benefit of priority to U.S. Provisional Patent Application Ser. No. 61/635,442, filed Apr. 19, 2012, the contents of which are hereby incorporated by reference.

### GOVERNMENT SUPPORT

This invention was made with government support under Grant No. W911NF-07-D-0004 awarded by the Army Research Office. The government has certain rights in this invention.

### BACKGROUND OF THE INVENTION

Artificial surfaces that exhibit both hydrophobic and oleophobic properties, mimicking various naturally evolved biological systems, are desirable in many applications. Currently available synthetic materials mostly exhibit hydrophobicity only. In other words, there are few synthetic surfaces that display oleophobic properties, even though such surfaces are of high practical importance for resisting fingerprints and avoiding food stains on textiles.

Fluorine-containing coatings have low surface energy and have been extensively exploited to create superhydrophobic surfaces (i.e., with water contact angles (WCAs) higher than 150°). These fluorine-containing coatings have water-repellent properties, self-cleaning properties, and antifouling properties. However, the coatings often exhibit undesirably high WCA hysteresis) (>30°.

Ungrafted poly(perfluorodecyl acrylate) (p-PFDA) surfaces synthesized by initiated Chemical Vapor Deposition (iCVD) have been explored. By controlling the iCVD process conditions, either amorphous or semi-crystalline films can be formed. While the amorphous films displayed WCA hysteresis in the range of 20-30°, values of <9° were observed when crystallinity was present. Therefore, surface reconstruction (that is, the rearrangement or reorientation of the polymeric molecules upon exposure to a stimulus) contributes to the WCA hysteresis, but is inhibited by crystalline packing of the polymer chains. For example, for an amorphous p-PFDA film in the dry state, surface energy is minimized when the fluorinated groups orient outward from the surface (high advancing WCA). However, exposure to water provides a driving force for the fluorinated groups to reorient inward, reducing the WCA (low receding WCA).

Poly(perfluorodecyl acrylate) has a strong tendency to crystallize in a smectic B phase, consisting of a succession of bilayers with a periodicity of roughly 32.4 Å. The bilayer results from pairing of pendant perfluorinated groups from two different polymer chains. The perfluorinated side chains are oriented perpendicular to the main polymer chains. The main chains exhibit hexagonal lamellar packing with a lattice parameter of roughly 6.4 Å. Depending on the iCVD deposition conditions, the perfluorinated chains change their orientation with respect to the substrate from perpendicular orientation (fiber-like texture) to horizontal with the substrate surface.

There exists a need for films of crystalline polymers comprising perfluoroalkyl moieties (e.g., poly(perfluoroalkyl acrylate)) for superhydrophobic and oleophobic applications.

### SUMMARY OF THE INVENTION

In certain embodiments, the invention relates to a composition, wherein the composition comprises a substrate and a coating material, wherein the coating material comprises a polymer; and the polymer comprises a plurality of pendant perfluorinated alkyl moieties.

In certain embodiments, the invention relates to any one of the aforementioned compositions, wherein the polymer is made from a monomer selected from the group consisting of acrylates, vinyl compounds, acetylenes, and organosilicons; the monomer comprises a pendant perfluorinated alkyl moiety; the pendant perfluorinated alkyl moiety is represented by —(CF₂)ₓCF₃; and x is an integer from 1 to 12, inclusive. In certain embodiments, the monomer is a diacrylate, methacrylic acid-co-ethyl acrylate, methacrylate, ethylene glycol dimethacrylate, dimethacrylate, methacrylic acid, acrylic acid, cyclohexyl methacrylate, glycidyl methacrylate, propargyl methacrylate, pentafluorophenyl methacrylate, furfuryl methacrylate, styrene, styrene derivatives, dimethylaminomethyl styrene, 4-amino styrene, maleic anhydride-alt-styrene, divinylbenzene, p-divinylbenzene, vinylimidazole, vinyl pyrrolidone, divinyloxybutane, N-isopropylacrylimide, diethylene glycol divinyl ether, phenyl acetylene, or siloxane.

In certain embodiments, the invention relates to any one of the aforementioned compositions, wherein the polymer comprises poly(1H,1H,2H,2H-perfluorodecyl acrylate).

In certain embodiments, the invention relates to any one of the aforementioned compositions, wherein the coating material is covalently bonded to the substrate.

In certain embodiments, the invention relates to any one of the aforementioned compositions, wherein the substrate is plastic, silicon, quartz, woven or non-woven fabric, paper, ceramic, nylon, carbon, polyester, polyurethane, polyanhydride, polyorthoester, polyacrylonitrile, polyphenazine, polyisoprene, synthetic rubber (for example, styrene-butadiene rubber), polytetrafluoroethylene (for example, Teflon® or Gore-tex®), polyethylene terephthalate (for example, Dacron), acrylate polymer, chlorinated rubber, fluoropolymer, polyamide resin, vinyl resin, expanded polytetrafluoroethylene (e-PTFE), low density polyethylene (LDPE), high density polyethylene (HDPE), or polypropylene (PP).

In certain embodiments, the invention relates to any one of the aforementioned compositions, wherein the advancing water contact angle is greater than about 150°.

In certain embodiments, the invention relates to any one of the aforementioned compositions, wherein the receding water contact angle is greater than about 150°.

In certain embodiments, the invention relates to any one of the aforementioned compositions, wherein the WCA hysteresis is less than about 10°.

In certain embodiments, the invention relates to any one of the aforementioned compositions, wherein the advancing mineral oil contact angle is greater than about 100°.

In certain embodiments, the invention relates to any one of the aforementioned compositions, wherein the receding mineral oil contact angle is greater than about 100°.

In certain embodiments, the invention relates to any one of the aforementioned compositions, wherein the static mineral oil contact angle is greater than about 100°.

In certain embodiments, the invention relates to any one of the aforementioned compositions, wherein the composition has a RMS roughness of greater than about 40 nm.

In certain embodiments, the invention relates to a method of coating a surface of a substrate, comprising the steps of:

providing a substrate;

exposing a surface of the substrate to plasma for a first period of time at a first pressure, thereby producing a conditioned surface of the substrate;

contacting the conditioned surface of the substrate with a vinyl precursor at a first temperature for a second period of time, thereby forming a surface comprising a plurality of pendant vinyl moieties; and

grafting a polymer to the plurality of pendant vinyl moieties, wherein the polymer comprises a plurality of pendant perfluorinated alkyl moieties.

In certain embodiments, the invention relates to any one of the aforementioned methods, wherein the vinyl precursor is trichlorovinylsilane.

In certain embodiments, the invention relates to any one of the aforementioned methods, wherein grafting the polymer to the vinyl moieties comprises initiated chemical vapor deposition (iCVD) of the polymer in a deposition chamber.

In certain embodiments, the invention relates to an article comprising any one of the aforementioned compositions.

In certain embodiments, the invention relates to any one of the aforementioned articles, wherein the article is, or is incorporated into, a fiber or a fabric.

### BRIEF DESCRIPTION OF THE FIGURES

FIG. 1 depicts (a) XRD profiles for p-PFDA coatings when grafted and when ungrafted to the silicon wafer surface. The XRD diffraction patterns are taken at both 0° and 90° with respect to the surface normal. For the grafted p-PFDA, the peaks sharpen when irradiating the sample at 0°, indicating that there is a preferential orientation of the chains. The ungrafted p-PFDA shows a very weak diffraction at both 90° and 0°. All the spectra were normalized by the sample thickness. (b) XPS F/C elemental ratio plotted as a function of the take-off angle in angle resolved XPS (ARXPS) analysis. Higher angles with the surface normal correspond to lower penetration depth (estimated to be 2.5 nm at 70°), while lower angles correspond to analysis of electrons coming from deeper layers (maximum depth achievable at 0° for this material has been estimated at around 7 nm). The trends show that the grafted sample has a small depletion of F from the surface to the measured depth, while for the ungrafted sample the depletion layer is significantly deeper.

FIG. 2 depicts profiles of a droplet of mineral oil deposited on ungrafted (a) and grafted (b) p-PFDA. The grafted sample shows oleophobicity (CA=108±0.8°), while the ungrafted sample show poor olephobicity (CA=51±2°). Topographical atomic force microscopy (AFM) images of the surfaces of the ungrafted (c) and grafted (d) p-PFDA coating. The lateral scale is 5×5 μm² on both images. The grafting of the fluorochains induces the formation of bigger aggregates (400 nm wide and 200 nm high). Scanning electron microscopy (SEM) images of the surface top view (e and f) and in cross-section (g and i) for the ungrafted (left) and grafted (right) samples. The SEM images confirm the roughening of the grafted sample.

FIG. 3 depicts a schematic representation of the grafting process. Vinyl groups were covalently bonded to the surface of a silicon wafer through a silane-based pretreatment. In one proposed mechanism, the initiator radicals react with the vinyl groups on the surface, creating radicals on the surface, creating anchor points for the monomer to react and be covalently bonded to the surface. The subsequent layer of monomer self-organizes in a double layer structure. We speculate the final thickness of the coating (200 nm) is a result of subsequent deposition of bilayer structures on the top of each other.

FIG. 4 is a tabulated comparison of deposition kinetics (deposition rate) and properties (roughness and contact angles, CA) for ungrafted and grafted samples. The CAs were calculated based on five drops deposited on the same sample surface and averaged, resulting in a maximum standard deviation of ±4°.

FIG. 5 depicts a schematic of a single oil droplet on a monolayer of polymer deposited by iCVD. Here, the perfluoroalkyl chains are oriented perpendicular to the substrate surface. θ represents the contact angle.

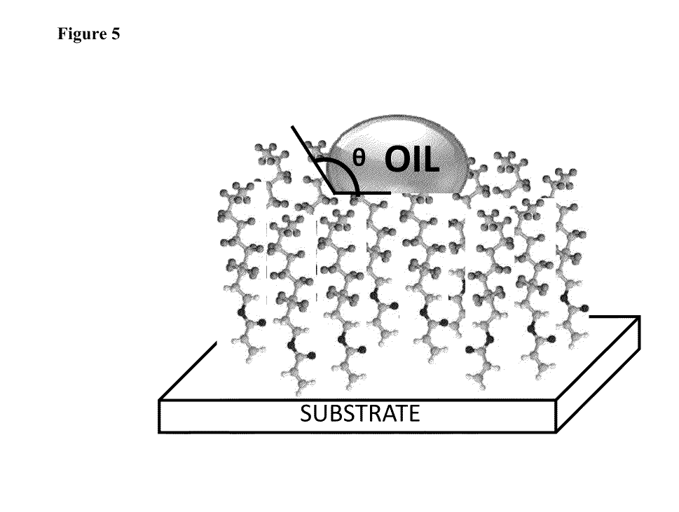

### DETAILED DESCRIPTION OF THE INVENTION

### Overview

In certain embodiments, the invention relates to a grafted p-PFDA film, wherein the grafted p-PFDA film: (a) is superhydrophobic (advancing WCA of about 160°), (b) displays low hysteresis (receding WCA of about 155°), and (c) displays oleophobicity (advancing contact angle with mineral oil of about 120°).

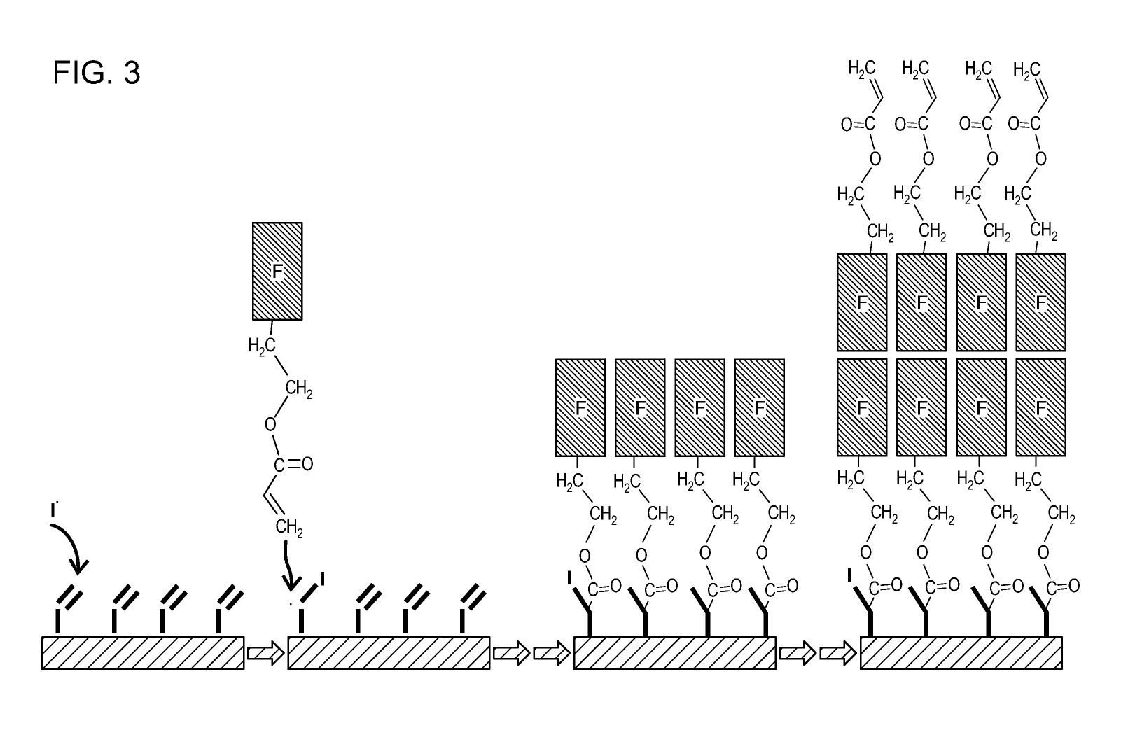

In certain embodiments, the invention relates to a method of grafting a polymer to the surface of a substrate, for example, as depicted in FIG. 3. In certain embodiments, the substrate is a silicon wafer. In certain embodiments, the silicon wafer is treated with oxygen plasma to remove any organic impurities and to increase the surface hydroxyl concentration. In certain embodiments, subsequent exposure of the treated Si substrate to tricholorovinylsilane vapor produces covalently bound vinyl groups on the surface. In certain embodiments, the pretreated substrate is then subjected to an iCVD process. During iCVD, the molecules of a radical initiator (I₂) (for example, tert-butyl peroxide, TBPO) are thermally cleaved by a filament array heated at about, for example, 290° C. This temperature is enough to break only the labile peroxide bond of the TBPO, while the monomer molecule is preserved. The radicals (I.) created by the decomposition of the TBPO react with the vinyl bonds on the surface, creating alkyl radicals on the surface (FIG. 3). These surface radicals provide the anchor points for synthesizing grafted polymer chains. In certain embodiments, by holding the substrate temperature low (for example, at about 40° C.), additional monomer units absorb or adsorb on the surface and react with the surface radical, thus increasing the chain length of the polymer brush.

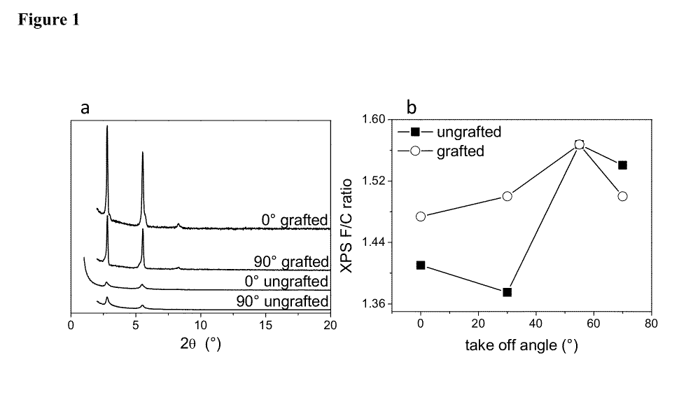

FIG. 1(a) compares the X-ray diffraction (XRD) 2-theta scans of grafted and ungrafted coatings. Other than the pretreatment, these samples were grown under identical iCVD conditions. The ungrafted coating is primarily amorphous, displaying a very weak diffraction pattern at incident beam angles of 0° and 90°. In contrast, grafting enhances the formation of crystalline structure formation as evidenced by the sharp intense peaks in the small-angle region (θ<10°), at θ=2.8°, 5.6°, 8.3° (corresponding to spacing d=32.4, 16.2, 10.8 Å, respectively). The d-spacing of 16.2 Å is precisely the length of a single perfluorinated side chain, whereas 32.4 Å represents a double layer (FIG. 3). The 10.8-Å peak corresponds to the length of the non-fluorinated spacer group. The double perfluorinated chains do not interpenetrate, probably due to the large size and rigidity of the pendant groups. The higher intensity obtained when the beam was oriented at 0° with respect to the substrate normal indicates that the p-PFDA coating grafted on the substrate shows texturing with a preference for the lamellar structure to be oriented parallel to the substrate with the fluorinated groups oriented almost perpendicular to the substrate surface. This organization can be likened to a fiber texture.

The influence of crystallinity on surface chemistry of the p-PFDA coatings was evaluated by means of angle-resolved XPS (ARXPS). FIG. 1(b) shows the X-ray photoelectron spectroscopy (XPS) F/C elemental ratio for the two samples measured at different take-off angles from 0° to 70° with respect to the surface normal. Lower take-off angles correspond to higher penetration depth. In particular, at 690 eV, 0° corresponds to ˜7 nm and 70° corresponds to about 2.5 nm. The penetration depths have been estimated using an inelastic mean free path (IMFP) of 2.4 nm because most of the polymers have IMFPs in the range 2.6-2.3 nm at 700 eV. The two trends of the F/C ratio as a function of the penetration depth are significantly different. The fluorine content segregates at the surface to minimize the energy at the film's interface with the air, creating a depletion of F in the deeper layer. In the case of the ungrafted sample, the depletion layer is thicker than for the grafted one. This result demonstrates the higher chain mobility of amorphous component. The surface reorganization becomes less prevalent as crystallinity increases due to reduced chain mobility.

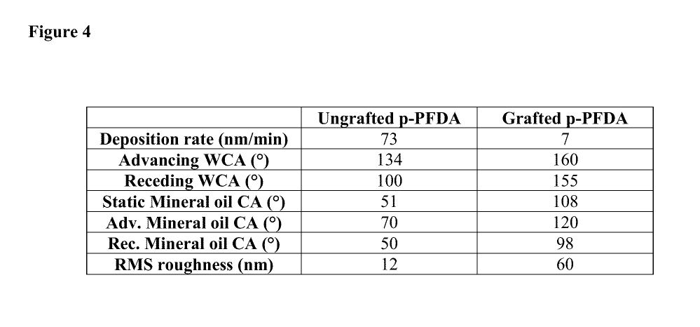

FIG. 4 summarizes the way in which crystalline phase formation affects deposition kinetics, hydrophobicity, oleophobicity, and surface morphology. The effect of the molecular organization is evident; in fact, the coating properties are different while the deposition conditions—and therefore the chemical composition of the polymers—are the same. The only difference between the two samples is the pretreatment of the substrate. The deposition rate substantially decreases from 73 to 7 nm/min for the grafted p-PFDA coating; this result mirrors previously reported results regarding the onset of crystallinity in ungrafted samples under other iCVD conditions. Formation of the smectic B phase appears to be a slow process that decreases the deposition rate.

The crystallinity also impacts the observed dynamic water contact angles (WCA), both advancing and receding angles, and the hysteresis (i.e., the difference between the two WCA values). FIG. 4 shows that the advancing and receding WCAs are different for the two samples. The ungrafted sample is hydrophobic: the advancing WCA is 134°. However, the hydrophobicity of the ungrafted sample strongly decreases after the contact with the water droplet; in fact, the measured receding contact angle is merely 100°. Remarkably, the grafted sample is superhydrophobic: the advancing and receding WCAs are 160° and 155°, respectively. Since the coating chemistry is the same for both grafted and ungrafted samples, the superhydrophobic properties measured for the grafted sample can be ascribed to a different morphology, or to the molecular organization in crystalline domains. In certain embodiments, the contact angles are measured with liquids at ambient temperature (for example, about 20° C., about 21° C., about 22° C., about 23° C., about 24° C., or about 25° C.). In general, surfaces that are strongly non-wetting to water, and with lower hysteresis, can be realized by roughening the contacting surface in order to trap numerous pockets of air underneath the liquid (the Cassie-Baxter regime).

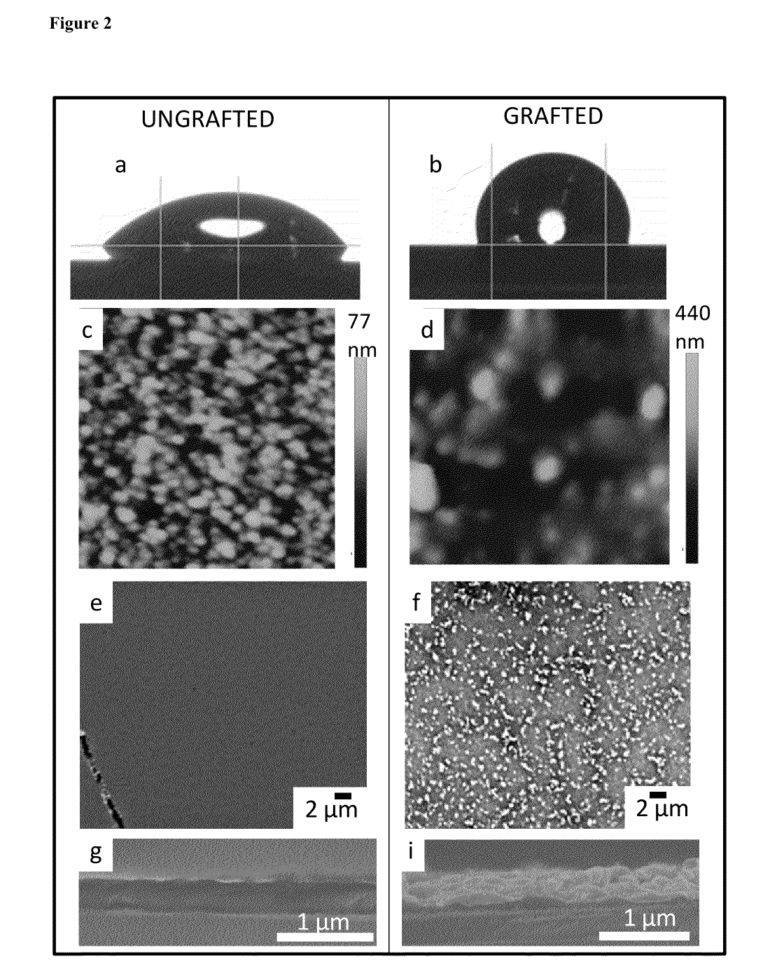

The oleophobicity of the two samples was also tested. FIGS. 2(a) and 2(b) show the profiles of mineral oil droplets deposited on the surfaces of the ungrafted and grafted samples, respectively. The sample with ungrafted chains was not mineral oil-repellent; rather, the static contact angle was quite low (51°), while the advancing CA was 70°. Remarkably, the sample with grafted p-PFDA displayed oleophobicity: The measured static and advancing mineral oil contact angles were 108° and 120°, respectively. Similar to the non-wetting properties described above, oil repellency can also be a function of the morphology of the sample.

The topography of the samples was investigated. FIGS. 2(c) and 2(d) show AFM images of the surfaces of the two coatings, while FIGS. 2(e)-2(i) show SEM images of the same surfaces, top-view (e and f) and in cross-section (g and i). The root-mean-square (RMS) roughness calculated for the grafted sample was 60 nm, while the ungrafted sample showed a relatively smooth morphology (RMS roughness of 12 nm). Island growth features can be observed for both samples; a high density of small islands is observed for the ungrafted sample, while the surface of the grafted sample shows a low density of much bigger islands. The islands may be clusters of crystalline grains. In the case of the pretreated sample, the islands are in average 400 nm wide and 200 nm high. In certain embodiments, the formation of bigger islands may be driven by the higher degree of crystallinity in the grafted sample. Fast Fourier Transform (FFT) analyses of the surfaces were also completed. The periodicity of the distribution of the islands on the two surfaces is different. For the ungrafted sample, the maximum amplitude is 2.5 nm, while for the grafted sample it is 22.4 nm. This different length scale, together with the limited surface rearrangement due to the crystallinity, appears to drive the observed differences in hydrophobicity and oleophobicity between the two samples. The bigger island features enhance the hydrophobicity of the coating in such a way that water is not allowed to fill the gaps and sticks on the surface, therefore the registered hysteresis is low, only 5° (so called slippery behavior). For the ungrafted sample, where the amorphous fraction predominates and the roughness is lower, the hysteresis is 34°.

In certain embodiments, grafting PFDA polymer chains to substrate is a powerful tool to enhance the crystalline order of the coating and obtain a fiber-like texture. The degree of crystallinity has important consequences for the coating properties. The crystalline domain formation hinders rapid polymer growth but induces the formation of a different morphology made of larger, round-shaped features. The different morphology and the reduced chain mobility form superhydrophobic coatings (adv WCA)=160° with extremely low hysteresis (5°) and oleophobicity (mineral oil contact angle of 108°).

### Initiated Chemical Vapor Deposition

Materials-processing often involves the deposition of films or layers on a surface of a substrate. One manner of effecting the deposition of such films or layers is through chemical vapor deposition (CVD). CVD involves a chemical reaction of vapor phase chemicals or reactants that contain the constituents to be deposited on the substrate. Reactant gases are introduced into a reaction chamber or reactor, and are decomposed and reacted at a heated surface to form the desired film or layer.

One method of CVD is initiated CVD (iCVD). In an iCVD process, thin filament wires are heated, thus supplying the energy to fragment a thermally-labile initiator, thereby forming a radical at moderate temperatures. The use of an initiator not only allows the chemistry to be controlled, but also accelerates film growth and provides control of molecular weight and rate. The energy input is low due to the low filament temperatures, but high growth rates may be achieved. The process progresses independent from the shape or composition of the substrate, is easily scalable, and easily integrated with other processes.

In certain embodiments, iCVD takes place in a reactor. In certain embodiments, a variety of monomer species may be polymerized and deposited by iCVD; these monomer species are well-known in the art. In certain embodiments, the surface to be coated is placed on a stage in the reactor and gaseous precursor molecules are fed into the reactor; the stage may be the bottom of the reactor and not a separate entity. In certain embodiments, a variety of carrier gases are useful in iCVD; these carrier gases are well-known in the art.

In certain embodiments, the iCVD reactor has automated electronics to control reactor pressure and to control reactant flow rates. In certain embodiments, any unreacted vapors may be exhausted from the system.

In certain embodiments, the iCVD coating process can take place at a range of pressures from atmospheric pressure to low vacuum. In certain embodiments, the pressure is less than about 50 torr. In certain embodiments, the pressure is less than about 40 torr. In certain embodiments, the pressure is less than about 30 torr. In certain embodiments, the pressure is less than about 20 torr. In certain embodiments, the pressure is less than about 10 torr. In certain embodiments, the pressure is less than about 5 torr. In certain embodiments, the pressure is less than about 1 torr. In certain embodiments, the pressure is less than about 0.7 torr. In certain embodiments, the pressure is less than about 0.4 torr. In certain embodiments, the pressure is about 50 torr. In certain embodiments, the pressure is about 40 torr. In certain embodiments, the pressure is about 30 torr. In certain embodiments, the pressure is about 20 torr. In certain embodiments, the pressure is about 10 torr. In certain embodiments, the pressure is about 5 torr. In certain embodiments, the pressure is about 1 torr. In certain embodiments, the pressure is about 0.7 torr. In certain embodiments, the pressure is about 0.4 torr. In certain embodiments, the pressure is about 0.2 torr. In certain embodiments, the pressure is about 0.1 torr. In certain embodiments the pressure is about 1 torr; about 0.9 torr; about 0.8 torr; about 0.7 torr; about 0.6 torr; about 0.5 torr; about 0.4 torr; about 0.3 torr; about 0.2 torr; or about 0.1 torr. In certain embodiments, the pressure is greater than about 1 mtorr.

In certain embodiments, the flow rate of the monomer can be adjusted in the iCVD method. In certain embodiments, the monomer flow rate is about 100 sccm (standard cubic centimeters per minute). In certain embodiments, the monomer flow rate is about 90 sccm. In certain embodiments, the monomer flow rate is about 80 sccm. In certain embodiments the monomer flow rate is about 70 sccm. In certain embodiments, the monomer flow rate is about 60 sccm. In certain embodiments, the monomer flow rate is about 50 sccm. In certain embodiments, the monomer flow rate is about 40 sccm. In certain embodiments, the monomer flow rate is about 30 sccm. In certain embodiments, the monomer flow rate is about 20 sccm. In certain embodiments, the monomer flow rate is less than about 100 sccm. In certain embodiments, the monomer flow rate is less than about 90 sccm. In certain embodiments, the monomer flow rate is less than about 80 sccm. In certain embodiments, the monomer flow rate is less than about 70 sccm. In certain embodiments, the monomer flow rate is less than about 60 sccm. In certain embodiments, the monomer flow rate is less than about 50 sccm. In certain embodiments, the monomer flow rate is less than about 40 sccm. In certain embodiments, the monomer flow rate is less than about 30 sccm. In certain embodiments, the monomer flow rate is less than about 20 sccm. In certain embodiments, the monomer flow rate is about 15 sccm. In certain embodiments, the flow rate is less than about 15 sccm. In certain embodiments, the monomer flow rate is about 14 sccm. In certain embodiments, the flow rate is less than about 14 sccm. In certain embodiments, the monomer flow rate is about 13 sccm. In certain embodiments, the flow rate is less than about 13 sccm. In certain embodiments, the monomer flow rate is about 12 sccm. In certain embodiments, the flow rate is less than about 12 sccm. In certain embodiments, the monomer flow rate is about 11 sccm. In certain embodiments, the flow rate is less than about 11 sccm. In certain embodiments, the monomer flow rate is about 10 sccm. In certain embodiments, the flow rate is less than about 10 sccm. In certain embodiments, the monomer flow rate is about 9 sccm. In certain embodiments, the flow rate is less than about 9 sccm. In certain embodiments, the monomer flow rate is about 8 sccm. In certain embodiments, the flow rate is less than about 8 sccm. In certain embodiments, the monomer flow rate is about 7 sccm. In certain embodiments, the flow rate is less than about 7 sccm. In certain embodiments, the monomer flow rate is about 6 sccm. In certain embodiments, the flow rate is less than about 6 sccm. In certain embodiments, the monomer flow rate is about 5 sccm. In certain embodiments, the flow rate is less than about 5 sccm. In certain embodiments, the monomer flow rate is about 3 sccm. In certain embodiments, the flow rate is less than about 3 sccm. In certain embodiments, the monomer flow rate is about 1.5 sccm. In certain embodiments, the flow rate is less than about 1.5 sccm. In certain embodiments, the monomer flow rate is about 0.75 sccm. In certain embodiments, the flow rate is less than about 0.75 sccm. In certain embodiments, the monomer flow rate is about 0.6 sccm. In certain embodiments, the flow rate is less than about 0.6 sccm. In certain embodiments, the monomer flow rate is about 0.5 sccm. In certain embodiments, the flow rate is less than about 0.5 sccm. When more than one monomer is used (i.e., to deposit co-polymers), the flow rate of the additional monomers, in certain embodiments, may be the same as those presented above.

In certain embodiments, the temperature of the monomer can be adjusted in the iCVD method. In certain embodiments, the monomer can be heated and delivered to the chamber by a heated mass flow controller. In certain embodiments, the monomer can be heated and delivered to the chamber by a needle valve. In certain embodiments, the monomer is heated at about 30° C., about 35° C., about 40° C., about 45° C., about 50° C., about 55° C., about 60° C., about 65° C., about 70° C., about 75° C., about 80° C., about 85° C., about 90° C., about 95° C., or about 100° C.

In certain embodiments, the flow rate of the initiator can be adjusted in the iCVD method. In certain embodiments the initiator flow rate is about 100 sccm. In certain embodiments, the initiator flow rate is about 90 sccm. In certain embodiments, the initiator flow rate is about 80 sccm. In certain embodiments, the initiator flow rate is about 70 sccm. In certain embodiments, the initiator flow rate is about 60 sccm. In certain embodiments, the initiator flow rate is about 50 sccm. In certain embodiments, the initiator flow rate is about 40 sccm. In certain embodiments, the initiator flow rate is about 30 sccm. In certain embodiments, the initiator flow rate is about 20 sccm. In certain embodiments, the initiator flow rate is less than about 100 sccm. In certain embodiments, the initiator flow rate is less than about 90 sccm. In certain embodiments, the initiator flow rate is less than about 80 sccm. In certain embodiments, the initiator flow rate is less than about 70 sccm. In certain embodiments, the initiator flow rate is less than about 60 sccm. In certain embodiments, the initiator flow rate is less than about 50 sccm. In certain embodiments, the initiator flow rate is less than about 40 sccm. In certain embodiments, the initiator flow rate is less than about 30 sccm. In certain embodiments, the initiator flow rate is less than about 20 sccm. In certain embodiments, the initiator flow rate is about 10 sccm. In certain embodiments, the flow rate is less than about 10 sccm. In certain embodiments, the initiator flow rate is about 5 sccm. In certain embodiments, the flow rate is less than about 5 sccm. In certain embodiments, the initiator flow rate is about 3 sccm. In certain embodiments, the flow rate is less than about 3 sccm. In certain embodiments, the initiator flow rate is about 1.5 sccm. In certain embodiments, the flow rate is less than about 1.5 sccm. In certain embodiments, the initiator flow rate is about 0.75 sccm. In certain embodiments, the flow rate is less than about 0.75 sccm. In certain embodiments, the initiator flow rate is about 0.5 sccm. In certain embodiments, the flow rate is less than about 0.5 sccm. In certain embodiments, the initiator flow rate is about 0.4 sccm. In certain embodiments, the flow rate is less than about 0.4 sccm. In certain embodiments, the initiator flow rate is about 0.3 sccm. In certain embodiments, the flow rate is less than about 0.3 sccm. In certain embodiments, the initiator flow rate is about 0.2 sccm. In certain embodiments, the flow rate is less than about 0.2 sccm. In certain embodiments, the initiator flow rate is about 0.1 sccm. In certain embodiments, the flow rate is less than about 0.1 sccm. In certain embodiments, a variety of initiators are useful in iCVD; these initiators are well-known in the art.

In certain embodiments, the carrier gas is an inert gas. In certain embodiments, the carrier gas is nitrogen or argon.

In certain embodiments, the flow rate of the carrier gas can be adjusted in the iCVD method. In certain embodiments, the carrier gas flow rate is about 1000 sccm. In certain embodiments, the carrier gas flow rate is about 900 sccm. In certain embodiments, the carrier gas flow rate is about 800 sccm. In certain embodiments, the carrier gas flow rate is about 700 sccm. In certain embodiments, the carrier gas flow rate is about 600 sccm. In certain embodiments, the carrier gas flow rate is about 500 sccm. In certain embodiments, the carrier gas flow rate is about 400 sccm. In certain embodiments, the carrier gas flow rate is about 300 sccm. In certain embodiments, the carrier gas flow rate is about 200 sccm. In certain embodiments, the carrier gas flow rate is about 100 sccm. In certain embodiments, the carrier gas flow rate is about 90 sccm. In certain embodiments, the carrier gas flow rate is about 80 sccm. In certain embodiments, the carrier gas flow rate is about 70 sccm. In certain embodiments, the carrier gas flow rate is about 60 sccm. In certain embodiments, the carrier gas flow rate is about 50 sccm. In certain embodiments, the carrier gas flow rate is about 40 sccm. In certain embodiments, the carrier gas flow rate is about 30 sccm. In certain embodiments, the carrier gas flow rate is about 20 sccm. In certain embodiments, the carrier gas flow rate is less than about 1000 sccm. In certain embodiments, the carrier gas flow rate is less than about 900 sccm. In certain embodiments, the carrier gas flow rate is less than about 800 sccm. In certain embodiments, the carrier gas flow rate is less than about 700 sccm. In certain embodiments, the carrier gas flow rate is less than about 600 sccm. In certain embodiments, the carrier gas flow rate is less than about 500 sccm. In certain embodiments, the carrier gas flow rate is less than about 400 sccm. In certain embodiments, the carrier gas flow rate is less than about 300 sccm. In certain embodiments, the carrier gas flow rate is less than about 200 sccm. In certain embodiments, the carrier gas flow rate is less than about 100 sccm. In certain embodiments, the carrier gas flow rate is less than about 90 sccm. In certain embodiments, the carrier gas flow rate is less than about 80 sccm. In certain embodiments, the carrier gas flow rate is less than about 70 sccm. In certain embodiments, the carrier gas flow rate is less than about 60 sccm. In certain embodiments the carrier gas flow rate is less than about 50 sccm. In certain, embodiments the carrier gas flow rate is less than about 40 sccm. In certain embodiments, the carrier gas flow rate is less than about 30 sccm. In certain embodiments, the carrier gas flow rate is less than about 20 sccm. In certain embodiments, the carrier gas flow rate is about 10 sccm. In certain embodiments, the flow rate is less than about 10 sccm. In certain embodiments, the carrier gas flow rate is about 5 sccm. In certain embodiments, the flow rate is less than about 5 sccm. In certain embodiments, the flow rate is greater than about 4 sccm.

In certain embodiments, the temperature of the filament can be adjusted in the iCVD method. In certain embodiments the temperature of the filament is about 350° C. In certain embodiments the temperature of the filament is about 300° C. In certain embodiments the temperature of the filament is about 250° C. In certain embodiments the temperature of the filament is about 245° C. In certain embodiments the temperature of the filament is about 235° C. In certain embodiments the temperature of the filament is about 225° C. In certain embodiments the temperature of the filament is about 200° C. In certain embodiments the temperature of the filament is about 150° C. In certain embodiments the temperature of the filament is about 100° C.

In certain embodiments, the filament is from about 0.1 cm to about 20 cm from the substrate stage. In certain embodiments, the filament is about 0.1 cm, about 0.2 cm, about 0.3 cm, about 0.4 cm, about 0.5 cm, about 0.6 cm, about 0.7 cm, about 0.8 cm, about 0.9 cm, about 1.0 cm, about 1.1 cm, about 1.2 cm, about 1.3 cm, about 1.4 cm, about 1.5 cm, about 1.6 cm, about 1.7 cm, about 1.8 cm, about 1.9 cm, about 2.0 cm, about 2.1 cm, about 2.2 cm, about 2.3 cm, about 2.4 cm, about 2.5 cm, about 3.0 cm, about 3.5 cm, about 4.0 cm, about 4.5 cm, about 5.0 cm, about 5.5 cm, about 6.0 cm, about 6.5 cm, about 7.0 cm, about 7.5 cm, about 8.0 cm, about 8.5 cm, about 9.0 cm, about 9.5 cm, about 10 cm, about 11 cm, about 12 cm, about 13 cm, about 14 cm, about 15 cm, about 16 cm, about 17 cm, about 18 cm, about 19 cm, or about 20 cm from the substrate stage. In certain embodiments, the filament is about 1.4 cm from the substrate stage.

In certain embodiments, the filament is oriented in any orientation with respect to the substrate stage or the chamber. In certain embodiments, the filament is oriented above the substrate stage, below the substrate stage, or beside the substrate stage.

In certain embodiments, the iCVD coating process can take place at a range of temperatures of the substrate stage. In certain embodiments, the temperature of the substrate stage is ambient temperature. In certain embodiments, the temperature of the substrate stage is about 25° C.; in yet other embodiments the temperature of the substrate stage is between about 25° C. and about 100° C., or between about 0° C. and about 25° C. In certain embodiments said temperature of the substrate stage is controlled by water.

In certain embodiments, the rate of polymer deposition is about 1 micron/minute. In certain embodiments, the rate of polymer deposition is between about 1 micron/minute and about 50 nm/minute. In certain embodiments, the rate of polymer deposition is between about 10 micron/minute and about 50 nm/minute. In certain embodiments, the rate of polymer deposition is between about 100 micron/minute and about 50 nm/minute. In certain embodiments, the rate of polymer deposition is between about 1 nm/minute and about 50 nm/minute. In certain embodiments, the rate of polymer deposition is between about 10 nm/minute and about 50 nm/minute. In certain embodiments, the rate of polymer deposition is between about 10 nm/minute and about 25 nm/minute.

### Compositions of the Invention

In certain embodiments, the invention relates to a composition, wherein the composition comprises a substrate and a coating material, wherein the coating material comprises a polymer; and the polymer comprises a plurality of pendant perfluorinated alkyl moieties.

In certain embodiments, the invention relates to any one of the aforementioned compositions, wherein the polymer is made from a monomer selected from the group consisting of acrylates, vinyl compounds, acetylenes, and organosilicons; the monomer comprises a pendant perfluorinated alkyl moiety; the pendant perfluorinated alkyl moiety is represented by —(CF₂)ₓCF₃; and x is an integer from 1 to 12, inclusive. In certain embodiments, the monomer is a diacrylate, methacrylic acid-co-ethyl acrylate, methacrylate, ethylene glycol dimethacrylate, dimethacrylate, methacrylic acid, acrylic acid, cyclohexyl methacrylate, glycidyl methacrylate, propargyl methacrylate, pentafluorophenyl methacrylate, furfuryl methacrylate, styrene, styrene derivatives, dimethylaminomethyl styrene, 4-amino styrene, maleic anhydride-alt-styrene, divinylbenzene, p-divinylbenzene, vinylimidazole, vinyl pyrrolidone, divinyloxybutane, N-isopropylacrylimide, diethylene glycol divinyl ether, phenyl acetylene, or siloxane.

In certain embodiments, the invention relates to any one of the aforementioned compositions, wherein the polymer comprises poly(1H,1H,2H,2H-perfluorodecyl acrylate).

In certain embodiments, the invention relates to any one of the aforementioned compositions, wherein the thickness of the coating material is from about 10 nm to about 1500 nm. In certain embodiments, the invention relates to any one of the aforementioned compositions, wherein the thickness of the coating material is about 10 nm, about 20 nm, about 30 nm, about 40 nm, about 50 nm, about 60 nm, about 70 nm, about 80 nm, about 90 nm, about 100 nm, about 125 nm, about 150 nm, about 175 nm, about 200 nm, about 225 nm, about 250 nm, about 275 nm, about 300 nm, about 325 nm, about 350 nm, about 375 nm, about 400 nm, about 425 nm, about 450 nm, about 475 nm, about 500 nm, about 525 nm, about 550 nm, about 575 nm, about 600 nm, about 625 nm, about 650 nm, about 675 nm, about 700 nm, about 725 nm, about 750 nm, about 775 nm, about 800 nm, about, 825 nm, about 850 nm, about 875 nm, about 900 nm, about 1000 nm, about 1100 nm, about 1200 nm, about 1300 nm, about 1400 nm, or about 1500 nm.

In certain embodiments, the invention relates to any one of the aforementioned compositions, wherein the coating material is covalently bonded to the substrate.

In certain embodiments, the invention relates to any one of the aforementioned compositions, wherein the substrate is homogeneous.

In certain embodiments, the invention relates to any one of the aforementioned compositions, wherein the substrate is heterogeneous.

In certain embodiments, the invention relates to any one of the aforementioned compositions, wherein the substrate is planar or non-planar.

In certain embodiments, the invention relates to any one of the aforementioned compositions, wherein the substrate is plastic, silicon, quartz, woven or non-woven fabric, paper, ceramic, nylon, carbon, polyester, polyurethane, polyanhydride, polyorthoester, polyacrylonitrile, polyphenazine, polyisoprene, synthetic rubber (for example, styrene-butadiene rubber), polytetrafluoroethylene (for example, Teflon® or Gore-tex®), polyethylene terephthalate (for example, Dacron), acrylate polymer, chlorinated rubber, fluoropolymer, polyamide resin, vinyl resin, expanded polytetrafluoroethylene (e-PTFE), low density polyethylene (LDPE), high density polyethylene (HDPE), or polypropylene (PP).

In certain embodiments, the invention relates to any one of the aforementioned compositions, wherein the surface of the substrate is concave or convex.

In certain embodiments, the invention relates to any one of the aforementioned compositions, wherein the advancing water contact angle is greater than about 150°. In certain embodiments, the invention relates to any one of the aforementioned compositions, wherein the advancing water contact angle is about 150°, about 155°, about 160°, about 165°, or about 170°.

In certain embodiments, the invention relates to any one of the aforementioned compositions, wherein the receding water contact angle is greater than about 150°. In certain embodiments, the invention relates to any one of the aforementioned compositions, wherein the receding water contact angle is about 150°, about 155°, about 160°, about 165°, or about 170°.

In certain embodiments, the invention relates to any one of the aforementioned compositions, wherein the WCA hysteresis is less than about 10°. In certain embodiments, the invention relates to any one of the aforementioned compositions, wherein the WCA hysteresis is about 10°, about 9°, about 8°, about 7°, about 6°, about 5°, about 4°, or about 3°.

In certain embodiments, the invention relates to any one of the aforementioned compositions, wherein the advancing mineral oil contact angle is greater than about 100°. In certain embodiments, the invention relates to any one of the aforementioned compositions, wherein the advancing mineral oil contact angle is about 100°, about 105°, about 110°, about 115°, about 120°, about 125°, or about 130°.

In certain embodiments, the invention relates to any one of the aforementioned compositions, wherein the receding mineral oil contact angle is greater than about 100°. In certain embodiments, the invention relates to any one of the aforementioned compositions, wherein the receding mineral oil contact angle is about 100°, about 105°, about 110°, about 115°, about 120°, about 125°, or about 130°.

In certain embodiments, the invention relates to any one of the aforementioned compositions, wherein the static mineral oil contact angle is greater than about 100°. In certain embodiments, the invention relates to any one of the aforementioned compositions, wherein the static mineral oil contact angle is about 100°, about 105°, about 110°, or about 115°.

In certain embodiments, the invention relates to any one of the aforementioned compositions, wherein the composition has a RMS roughness of greater than about 40 nm. In certain embodiments, the invention relates to any one of the aforementioned compositions, wherein the composition has a RMS roughness of about 40 nm, about 45 nm, about 50 nm, about 55 nm, about 60 nm, about 65 nm, or about 70 nm.

Another aspect of the invention relates to the composition obtained by the process of any one of methods discussed below.

### METHODS OF THE INVENTION

In certain embodiments, the invention relates to a method of coating a surface of a substrate, comprising the steps of:

providing a substrate;

exposing a surface of the substrate to plasma for a first period of time at a first pressure, thereby producing a conditioned surface of the substrate;

contacting the conditioned surface of the substrate with a vinyl precursor at a first temperature for a second period of time, thereby forming a surface comprising a plurality of pendant vinyl moieties; and

grafting a polymer to the plurality of pendant vinyl moieties, wherein the polymer comprises a plurality of pendant perfluorinated alkyl moieties.

In certain embodiments, the invention relates to any one of the aforementioned methods, wherein the plasma is an oxygen plasma.

In certain embodiments, the invention relates to any one of the aforementioned methods, wherein the first period of time is about 2 s to about 4 min. In certain embodiments, the invention relates to any one of the aforementioned methods, wherein the first period of time is about 2 s, about 3 s, about 4 s, about 5 s, about 6 s, about 7 s, about 8 s, about 9 s, about 10 s, about 11 s, about 12 s, about 13 s, about 14 s, about 15 s, about 16 s, about 17 s, about 18 s, about 19 s, about 20 s, about 25 s, about 30 s, about 35 s, about 40 s, about 45 s, about 50 s, about 55 s, about 60 s, about 90 s, about 120 s, about 150 s, about 3 min, about 3.5 min, or about 4 min.

In certain embodiments, the invention relates to any one of the aforementioned methods, wherein the flow rate of oxygen is about 10 sccm to about 100 sccm. In certain embodiments, the invention relates to any one of the aforementioned methods, wherein the flow rate of oxygen is about 10 sccm, about 20 sccm, about 30 sccm, about 40 sccm, about 50 sccm, about 60 sccm, about 70 sccm, about 80 sccm, about 90 sccm, or about 100 sccm.

In certain embodiments, the invention relates to any one of the aforementioned methods, wherein the first pressure is about 5 mTorr to about 250 mTorr. In certain embodiments, the invention relates to any one of the aforementioned methods, wherein the first pressure is about 5 mTorr, about 10 mTorr, about 15 mTorr, about 20 mTorr, about 25 mTorr, about 30 mTorr, about 35 mTorr, about 40 mTorr, about 45 mTorr, about 50 mTorr, about 75 mTorr, about 100 mTorr, about 125 mTorr, about 150 mTorr, about 175 mTorr, about 200 mTorr, about 225 mTorr, or about 250 mTorr.

In certain embodiments, the invention relates to any one of the aforementioned methods, wherein the plasma is generated by applying about 50 W/cm² to about 300 W/cm². In certain embodiments, the invention relates to any one of the aforementioned methods, wherein the plasma is generated by applying about 50 W/cm², about 75/cm², about 100 W/cm², about 125 W/cm², about 150 W/cm², about 175 W/cm², about 200 W/cm², about 225 W/cm², about 250 W/cm², about 275 W/cm², or about 300 W/cm².

In certain embodiments, the invention relates to any one of the aforementioned methods, further comprising the step of

exposing the conditioned substrate to nitrogen a second pressure at a second temperature for a third period of time.

In certain embodiments, the invention relates to any one of the aforementioned methods, wherein the second temperature is from about 35° C. to about 80° C. In certain embodiments, the invention relates to any one of the aforementioned methods, wherein the second temperature is about 35° C., about 40° C., about 45° C., about 50° C., about 55° C., about 60° C., about 65° C., about 70° C., about 75° C., or about 80° C.

In certain embodiments, the invention relates to any one of the aforementioned methods, wherein the third period of time is about 1 min to about 10 min. In certain embodiments, the invention relates to any one of the aforementioned methods, wherein the third period of time is about 1 min, about 2 min, about 3 min, about 4 min, about 5 min, about 6 min, about 7 min, about 8 min, about 9 min, or about 10 min.

In certain embodiments, the invention relates to any one of the aforementioned methods, wherein the vinyl precursor is trichlorovinylsilane, dichlorodivinylsilane, trifluorovinylsilane, difluorodivinylsilane, trivinylsilane, or divinylsilane.

In certain embodiments, the invention relates to any one of the aforementioned methods, wherein the vinyl precursor is trichlorovinylsilane.

In certain embodiments, the invention relates to any one of the aforementioned methods, wherein the first temperature is from about 15° C. to about 40° C. In certain embodiments, the invention relates to any one of the aforementioned methods, wherein the first temperature is about 15° C., about 20° C., about 25° C., about 30° C., about 35° C., or about 40° C.

In certain embodiments, the invention relates to any one of the aforementioned methods, wherein the second period of time is from about 2 min to about 20 min. In certain embodiments, the invention relates to any one of the aforementioned methods, wherein the second period of time is about 2 min, about 3 min, about 4 min, about 5 min, about 6 min, about 7 min, about 8 min, about 9 min, about 10 min, about 11 min, about 12 min, about 13 min, about 14 min, or about 15 min.

In certain embodiments, the invention relates to any one of the aforementioned methods, wherein the deposition rate of the polymer onto the substrate is less than about 20 nm/min. In certain embodiments, the invention relates to any one of the aforementioned methods, wherein the deposition rate of the polymer onto the substrate is about 20 nm/min, about 18 nm/min, about 16 nm/min, about 14 nm/min, about 12 nm/min, about 10 nm/min, about 9 nm/min, about 8 nm/min, about 7 nm/min, about 6 nm/min, about 5 nm/min, about 4 nm/min, or about 3 nm/min.

In certain embodiments, the invention relates to any one of the aforementioned methods, wherein grafting the polymer to the vinyl moieties comprises initiated chemical vapor deposition (iCVD) of the polymer in a deposition chamber.

In certain embodiments, iCVD involves a gaseous initiator. In certain embodiments, the gaseous initiator is selected from the group consisting of tert-butyl peroxide, tert-amyl peroxide, triethylamine, tert-butyl peroxy benzoate, benzophenone, and 2,2′-azobis(2-methylpropane).

### APPLICATIONS AND ARTICLES OF THE INVENTION

In certain embodiments, the invention relates to an article comprising any one of the aforementioned compositions.

In certain embodiments, the invention relates to any one of the aforementioned articles, wherein the article is, or is incorporated into, a fiber or a fabric.

A major problem in making water repellant superhydrophobic fabrics has been the lack of an easy and inexpensive way of making these fabrics. Typically, water repellant fabrics have very poor quality (i.e., water is poorly repelled and doesn't really form an air layer between the water and raw fiber as is the case for truly superhydrophobic fibers). The higher quality superhydrophobic materials tend to be very expensive and structurally not amenable to coating fibers and fabrics.

Superhydrophobic, superrepellant and self-cleaning fibers could bring a large number of benefits to the textile industry. Super-repellent textile materials are extremely important in the manufacture of suits protective against chemical and biological weapons. Moreover, such fiber surfaces can be thought of as being liquid superconductors, with superhydrophobic fibers transporting fluids essentially on a bed of air. When water is passed over such a surface it will exhibit elements of a self-cleaning process. It is clear that superhydrophobic fibers and superhydrophobic-like substrates will revolutionize and extend the capability of many textile-based applications as well as create new product markets. Enhanced properties of many standard textile assemblies is expected, for example, a combination of hydrophilic fibers with superhydrophobic fibers will produce smart or extreme textile assemblies that will push moisture away from the body very rapidly and pull it through the fabric for quick drying.

In certain embodiments, articles of the invention display the ability to resist fingerprints. In certain embodiments, articles of the invention display the ability to prevent stains, contamination, corrosion, or damage to surfaces.

In certain embodiments, articles of the invention display antifouling properties.

### EXEMPLIFICATION

The invention now being generally described, it will be more readily understood by reference to the following examples, which are included merely for purposes of illustration of certain aspects and embodiments of the invention, and are not intended to limit the invention.

### Example 1

### General Procedures

The deposition chamber has been described previously. The liquid monomer (1H,1H,2H,2H-perfluorodecyl acrylate, PFDA, 97% Aldrich) and initiator (tert-Butyl Peroxide, TBPO, 98% Aldrich) were used without further purification. The monomer was vaporized in a jar maintained at 80° C., and was then introduced into the reactor through a needle valve. The initiator was kept at room temperature and introduced through a mass flow controller (MKS Instrument). The labile peroxide bond of the initiator was thermally broken by a filament array of 14 parallel Nickel Chromium filaments (Goodfellow) at a distance of 1.5 cm from the substrate. The filament (T_{fil}) and the substrate temperatures (T_{sub}) were monitored by two thermocouples (Type K, Omega Engineering). The substrate temperature was adjusted (with an error of ±2° C.) using a chiller/heater (NESLAB).

The silicon wafer substrate (p-type, Wafer World Inc.) was treated with oxygen plasma (100 Wcm⁻², 100 mTorr) for 2 min in order to clean the surface and create Si—OH groups. The substrate was then placed in a nitrogen purged vacuum oven (VWR, 1415 M) which was maintained at 60° C. and −30 in Hg gauge pressure. The nitrogen flow was stopped after 3 min and the substrate was exposed to trichlorovinylsilane (Aldrich, 98%) vapor for 5 to 10 min at room temperature in order to attach the vinyl groups on the substrate surface.

p-PFDA samples were coated on a tricholorovinylsilane-pretreated and an untreated silicon wafer. The deposition conditions were as follows: a monomer flow rate of 0.6 sccm, an initiator flow rate of 0.2 sccm, a pressure of 200 mTorr, the filament and substrate temperatures of 290° C. and 40° C., respectively. Each film was deposited up to a thickness of 200±10 nm, monitored real-time by reflecting a He—Ne laser (JDS Uniphase) off the substrate/thin film and recording the interference laser signal intensity as a function of time.

The film thicknesses were measured by ex-situ variable angle spectroscopy ellipsometry (VASE, JA Woollam M-2000). The measurements were done at three different angles (65°, 70° and 75°) in the wavelength range of 200-1000 nm. The applied optical model consisted of three components: the silicon substrate, the native SiO₂ layer of 1.7 nm and the film bulk layer. The bulk components were modeled by the Cauchy function adding the Urbach tail to model the absorption.

The crystalline states of the p-PFDA thin films were determined by X-ray diffraction (XRD). The XRD measurements were carried out on a Scintag Theta-theta diffractometer with a Cu K-alpha radiation (1.541867 Å) at 40 kV and 44 mA. Data were collected in continuous mode at 3°/min, with a step size of 0.02°. The scans were taken in symmetrical reflection geometry.

Contact angles (CA) were measured using a goniometer equipped with an automated dispenser (Model 500, Rame-Hart). Advancing and receding angles were measured with the sessile drop method by depositing a droplet of 1 μL on the surface, then increasing the volume to 4 μL, finally decreasing it. Advancing angles were considered as the maximum angles observed during the droplet growth. Receding contact angles were measured in correspondence of the drop profile just before the contact surface reduction. Each CA value was averaged from measurements of four drops with an estimated maximum error of 4°. The CA was measured using as liquid distilled water and mineral oil (Sigma Aldrich, CAS Number: 8042-47-5).

Surface film morphology was investigated by Atomic Force Microscopy (AFM-Digital Instruments, D3100-1). Images were acquired in tapping mode using conical gold-coated silicon tips. RMS roughness was measured on 5×5 μm² surface areas. Deposited trench wafers were sputter-coated with 6 nm of gold (Denton Desk V), and images were obtained by Scanning Electron Microscopy (SEM, Hitachi, TM 3000) with an acceleration voltage of 15 kV.

Elemental analysis was done using angle-resolved X-ray photoelectron spectroscopy (ARXPS). The XPS spectra were obtained using a SSX-100 X-probe (Surface Science Instruments) spectrometer equipped with a monochromatized Al K_{α} source, operated at 1486.8 eV. Survey scans were conducted, at take-off angles of 0°, 30°, 55° and 70° with the surface normal, to sample the surface at different penetration depths. During the XPS analysis, the sample charge was compensated by a 1 eV electron beam at high neutralization current by means of a Flood Gun. The pass energy was 150 V for survey scans and 50 V for high-resolution scans. The pressure during analysis was kept under 2×10⁻⁹ Ton. A 1-mm diameter beam was used in the analysis. CasaXPS software was used to fit the high-resolution spectra. Samples were stored under vacuum overnight prior to analysis.

### INCORPORATION BY REFERENCE

All of the U.S. patents and U.S. patent application publications cited herein are hereby incorporated by reference.

### EQUIVALENTS

Those skilled in the art will recognize, or be able to ascertain using no more than routine experimentation, many equivalents to the specific embodiments of the invention described herein. Such equivalents are intended to be encompassed by the following claims.

We claim:

1. A composition, wherein the composition comprises a substrate and a coating material, wherein the coating material comprises a polymer; and the polymer comprises a plurality of pendant perfluorinated alkyl moieties.

2. The composition of claim 1, wherein the polymer comprises poly(1H,1H,2H,2H-perfluorodecyl acrylate).

3. The composition of claim 1, wherein the thickness of the coating material is from about 10 nm to about 1500 nm.

4. The composition of claim 1, wherein the coating material is covalently bonded to the substrate.

5. The composition of claim 1, wherein the substrate is homogeneous.

6. The composition of claim 1, wherein the substrate is heterogeneous.

7. The composition of claim 1, wherein the substrate is planar or non-planar.

8. The composition of claim 1, wherein the substrate is plastic, silicon, quartz, woven or non-woven fabric, paper, ceramic, nylon, carbon, polyester, polyurethane, polyanhydride, polyorthoester, polyacrylonitrile, polyphenazine, polyisoprene, synthetic rubber, polytetrafluoroethylene, polyethylene terephthalate, acrylate polymer, chlorinated rubber, fluoropolymer, polyamide resin, vinyl resin, expanded polytetrafluoroethylene, low density polyethylene, high density polyethylene, or polypropylene.

9. The composition of claim 1, wherein the advancing water contact angle is greater than about 150°.

10. The composition of claim 1, wherein the receding water contact angle is greater than about 150°.

11. The composition of claim 1, wherein the WCA hysteresis is less than about 10°.

12. The composition of claim 1, wherein the advancing mineral oil contact angle is greater than about 100°.

13. The composition of claim 1, wherein the receding mineral oil contact angle is greater than about 100°.

14. The composition of claim 1, wherein the static mineral oil contact angle is greater than about 100°.

15. The composition of claim 1, wherein the composition has a RMS roughness of greater than about 40 nm.

16. A method of coating a surface of a substrate, comprising the steps of:
providing a substrate;
exposing a surface of the substrate to plasma for a first period of time at a first pressure, thereby producing a conditioned surface of the substrate;
contacting the conditioned surface of the substrate with a vinyl precursor at a first temperature for a second period of time, thereby forming a surface comprising a plurality of pendant vinyl moieties; and
grafting a polymer to the plurality of pendant vinyl moieties, wherein the polymer comprises a plurality of pendant perfluorinated alkyl moieties.

17. The method of claim 16, wherein the first period of time is about 2 s to about 4 min.

18. The method of claim 16, wherein the flow rate of oxygen is about 10 sccm to about 100 sccm.

19. The method of claim 16, wherein the first pressure is about 5 mTorr to about 250 mTorr.

20. The method of claim 16, wherein the plasma is generated by applying about 50 W/cm² to about 300 W/cm².

21. The method of claim 16, wherein the vinyl precursor is trichlorovinylsilane.

22. The method of claim 16, wherein the first temperature is from about 15° C. to about 40° C.

23. The method of claim 16, wherein the second period of time is from about 2 min to about 20 min.

24. The method of claim 16, wherein the deposition rate of the polymer onto the substrate is less than about 20 nm/min.

25. The method of claim 16, wherein grafting the polymer to the vinyl moieties comprises initiated chemical vapor deposition (iCVD) of the polymer in a deposition chamber.
